(19) United States
(12) Patent Application Publication
(10) Pub. No.: US 2005/0039100 A1
(43) Pub. Date: Feb. 17, 2005

(54) Method and system for automatic error recovery in an electronic mail system

(75) Inventors: Steven A. Bade, Georgetown, TX (US); Janice Marie Girouard, Austin, TX (US); Emily Jane Ratliff, Austin, TX (US)

Correspondence Address: BRACEWELL & PATTERSON, L.L.P., P.O. BOX 969, AUSTIN, TX, 78767-0969, US

(73) Assignee: International Business Machines Corporation

(21) Appl. No.: 10/640,822

(22) Filed: Aug. 14, 2003

(51) Int. Cl. H04L 1/00; G06F 11/00; G06F 11/30; H03M 13/00; G11C 29/00; G08C 25/00

(52) U.S. Cl. 714/746

(57) ABSTRACT

A method and system for automatic address error recovery in an electronic mail system where electronic mail messages are transferred by identifying an address which includes a user name and a domain name which includes a top level domain suffix. In the event an electronic mail message destination cannot be determined, likely appropriate destinations are automatically determined by systematically determining common alternate spellings of the user name, likely alternate domain names or an alternate top level domain suffix. Alternately, a table of expired addresses and corresponding new addresses can be maintained and examined to determine a likely appropriate address. At least one likely appropriate address is presented to a sender and the electronic mail message is then transmitted to a destination by the sender.

### BACKGROUND OF THE INVENTION

1. Technical Field

The present invention relates in general to electronic mail systems and in particular to methods and systems for enhanced efficiency in electronic mail systems. Still more particularly, the present invention relates to methods and systems for automatic address error recovery in an electronic mail system.

2. Description of the Related Art

Electronic mail or “e-mail” is rapidly supplanting traditional postal mail for the transmission of letters, messages, purchase of orders or the like over widespread communication networks. Such messages may be entered by a user at a personal computer and distributed throughout a network of computers, which may include mainframes, minicomputers and widespread computer networks. Some electronic mail systems may be limited to a single computer system or network within an enterprise; however, other electronic mail systems have access to multiple computer systems around the world, enabling users to send messages throughout the world.

Most electronic mail systems include a basic text editor for composing messages and typically permit a user to append or attach photographs, documents or other objects to be transmitted to the recipient along with the electronic mail message.

Electronic mail messages typically include a user name and a domain name which includes a top level domain suffix. Messages are then broadcast throughout the electronic mail network or a wider network, such as the World Wide Web, and processed by electronic mail servers or hosts throughout the system. Transmitted messages are typically stored in electronic mailboxes until the user of that mailbox opens the mailbox to check for electronic mail.

One problem which occurs with some frequency in electronic mail is the failure of the electronic mail item to be transmitted to the proper recipient due to an error, either in the address of the electronic mail message or as a result of a system error which prohibits the message from being delivered.

Electronic mail messages which are returned undelivered are referred to as “bounced” mail messages and typically are transmitted back to the sender with an error message which indicates why the electronic mail message was not successfully transmitted.

The reasons for failure of delivery of an electronic mail item may be multiple, but typically the failure is a result of an error within the address to which the electronic mail has been sent.

As noted above, each electronic mail item includes a user name and a domain name. The domain name is a direction to either the local electronic mail system or the wide network system to transmit the message to the particular domain associated with the user. Once the system makes contact with the appropriate mail server, within the domain name of the recipient, that mail server will examine the message to determine if the message will be allowed to pass through the server to the intended addressee.

Electronic mail systems may include the ability to block electronic mails from a particular address, or the server may fail to forward the electronic mail message as a result of excessive activity on the mail server at the time of receipt.

Once an electronic mail message has been accepted by the mail server at the recipient's domain it may still fail to be delivered as a result of an error within the user's name or if the recipient lacks sufficient memory space within his electronic mailbox to receive the electronic mail message.

The failure to successfully deliver an electronic mail message and the effort required by the sender of that message to retransmit the message make it clear that a need exists for a method and system which could automatically correct errors in the electronic mail message address which would prevent delivery.

### SUMMARY OF THE INVENTION

It is therefore one object of the present invention to provide and improve an electronic mail system.

It is another object of the present invention to provide an improved method and system for enhancing the efficiency of electronic mail systems.

It is yet another object of the present invention to provide a method and system for automatic address error recovery in an electronic mail system.

The foregoing objects are achieved as is now described. A method and system are disclosed for automatic address error recovery in an electronic mail system where electronic mail messages are transferred by identifying an address which includes a user name and a domain name, which includes a top level domain suffix. In the event an electronic mail message destination cannot be determined, likely appropriate destinations are automatically determined by, for example, systematically determining common alternate spellings or misspellings of the user name, likely alternate domain names or an alternate top level domain suffix. Alternately, a listing of expired addresses and corresponding new addresses can be examined automatically to determine a likely appropriate address. At least one likely appropriate address is then presented to the sender of the electronic mail message and the electronic mail message will then be transmitted to a destination selected by the sender from the presented addresses.

### BRIEF DESCRIPTION OF THE DRAWINGS

The novel features believed to be characteristic of the invention are set forth in the appended claims. The present invention itself, however, as well as a preferred mode of use, further objectives, and advantages thereof, will best be understood by reference to the following detailed description of a preferred embodiment when read in conjunction with the accompanying drawings, wherein:

FIG. 1 is a pictorial representation of a computer network which may be utilized to implement the method and system of the present invention;

FIG. 2 a pictorial representation of typical electronic mail item which may be address corrected in accordance with a method and system of the present invention;

FIG. 3 is a high level block diagram of an electronic mail server which may be utilized to implement the method and system of the present invention;

FIG. 4A is a pictorial representation of a user name correction table which may be utilized by the electronic mail server of FIG. 3 to implement the method and system of the present invention;

FIG. 4B is a pictorial representation of a domain name correction table which may be utilized by the electronic mail server of FIG. 3 to implement the method and system of the present invention;

FIG. 4C is a pictorial representation of a top level domain suffix correction table which may be utilized by the electronic mail server of FIG. 3 to implement the method and system of the present invention.

FIG. 4D is a pictorial representation of a former employee correction table which may be utilized by the electronic mail server of FIG. 3 to implement the method and system of the present invention; and

FIG. 5 is a high level logic flow chart illustrating the method of the present invention.

### DETAILED DESCRIPTION OF A PREFERRED EMBODIMENT

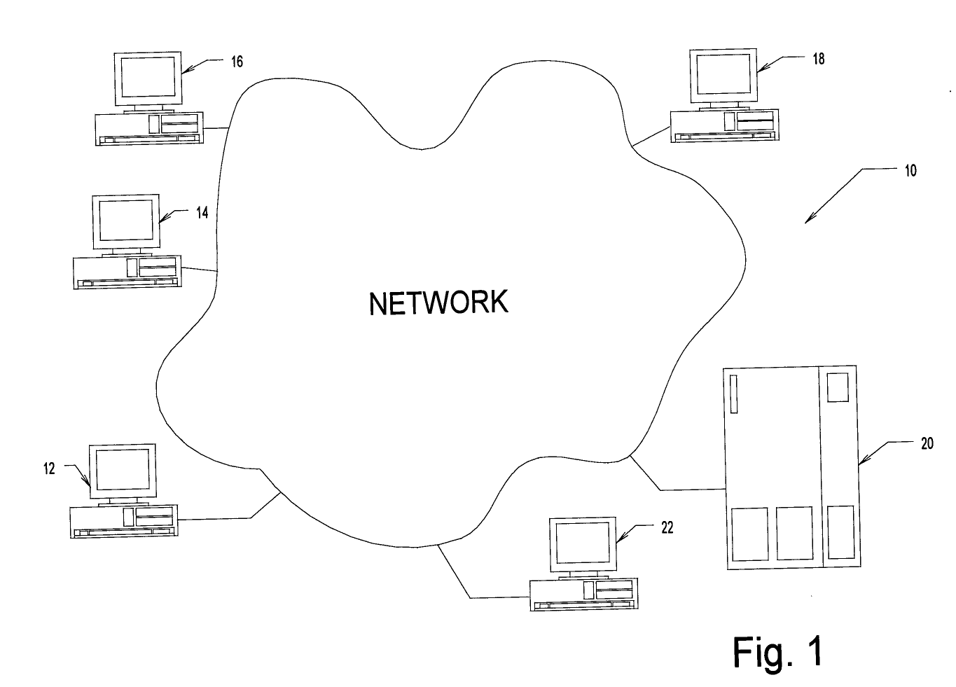

With reference now to the figures and in particular with reference to FIG. 1, there is depicted a pictorial representation of a computer network which may be utilized to implement the method and system of the present invention.

As illustrated, network 10 comprises a distributed network to which multiple computers, terminals or other such devices are electronically coupled. Network 10 may have multiple so-called “personal” computers 12, 14, 16, 18 and 22 attached thereto, as well as minicomputers, mainframes or similar devices, illustrated at reference numeral 20.

As those skilled in the art will appreciate, network 10 may comprise a network restricted to the confines of a particular business entity or may comprise the so-called “Internet” through which electronic mail messages may be transmitted on a world wide basis. The details of the interconnection of computers with network 10 are thought to be well within the knowledge of one having ordinary skill in the art and consequently, forms no part of the present disclosure.

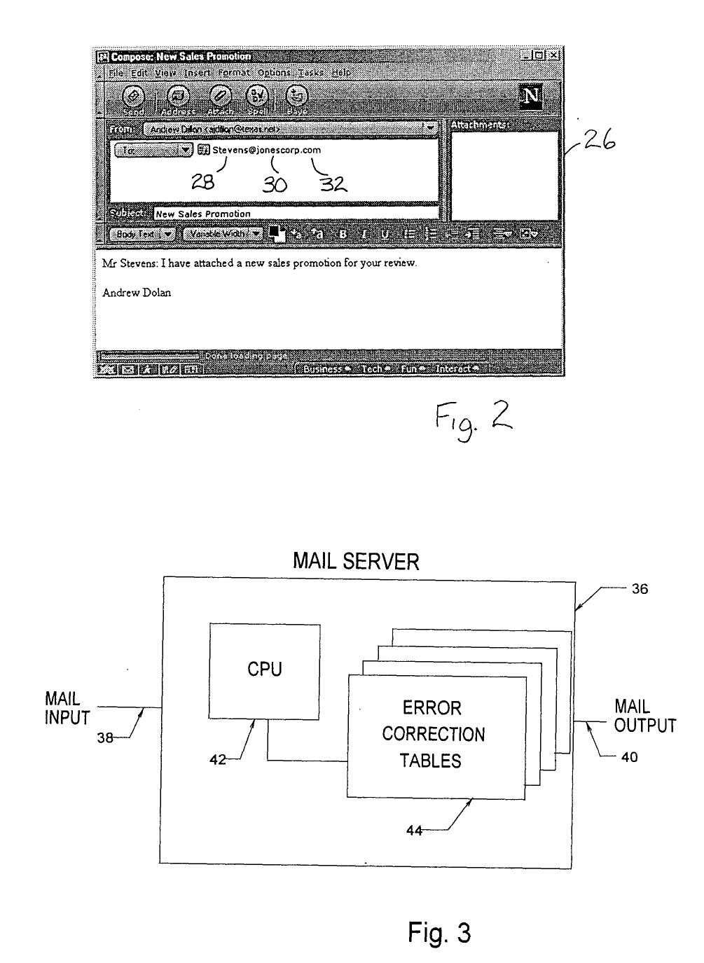

Referring now to FIG. 2, there is depicted a pictorial representation of a typical electronic mail item 26 which may be address corrected in accordance with the method and system of the present invention. As illustrated, mail item 26 includes a short textual message and an area which permits an attachment of documents, photographs or the like. The address portion of electronic mail item 26 includes an address which comprises a user name 28, a domain name 30 and a top level domain suffix 32. Those having ordinary skill in the art will appreciate that top level domain suffix 32 may comprise any of a plurality of available top level domain suffixes such as: “.com”; “.org”; “.net”; “.edu”; “.biz” and many others. Thus, there are at least three areas of possible error in the address of electronic mail item 26 which could result in the failure of delivery of that item.

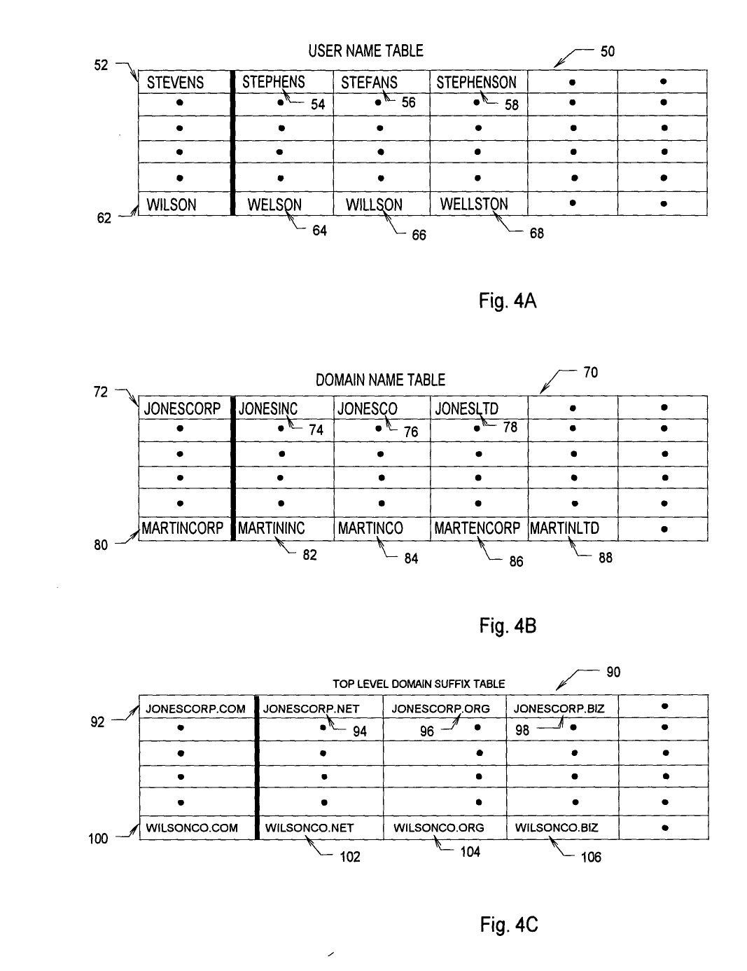

With reference now to FIG. 3, there is depicted a high level block diagram of an electronic mail server 36 which may be utilized to implement the method and system of the present invention. As illustrated, electronic mail items are input to mail server 36 at reference numeral 38, processed to determine if those mail items are appropriate for delivery and then output to the appropriate user at reference numeral 40. Mail server 36 may comprise a personal computer, minicomputer, mainframe computer or any other device having suitable processing power to accomplish the rudimentary process described herein.

As illustrated, mail server 36 includes a central processing unit 42 and multiple error correction tables 44. Each error correction table 44 may be utilized to correct a likely error within one portion of the address of electronic mail item 26 (see FIG. 2), in a manner which will be explained in greater detail herein. Of course, those skilled in the art will appreciate that error correction table 44 may comprise any suitable organized data structure and that tables are utilized merely for an illustrative purpose.

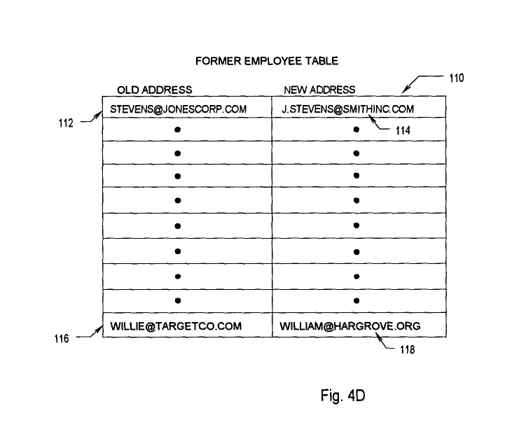

Referring now to FIG. 4A, there is depicted a pictorial representation of a user name correction table which may be utilized by electronic mail server 36 to implement the method and system of the present invention. As depicted, user name table 50 includes, as inputs, various electronic mail user names. Thus, as depicted at 52, the name “Stevens” is a point of entry to user name table 50. Stored in association with user name “Stevens” are multiple likely alternatives to that name. Thus, for example, at reference numeral 54 the name “Stephens” is stored. Similarly, “Stefans” is stored at 56 and “Stephenson” is stored at reference numeral 58. This short list is meant to be illustrative in nature and does not form a complete list of likely alternatives to the user name “Stevens” which provided the entry point to user table 50.

Another example within user name table 50 is user name “Wilson” as depicted at reference numeral 62. Various alternatives are listed including: “Welson” at reference numeral 64, “Willson” at reference numeral 66 and “Wellston” at reference numeral 68. Again, this list of likely appropriate alternatives is not believed to be exhaustive but serves as an illustration for the types of alternative spellings or variations which are possible utilizing the method and system of the present invention.

Thus, as illustrated within FIG. 4A, if the electronic mail message depicted within FIG. 2 is received at mail server 36 (see FIG. 3) and cannot be delivered, an error correction table comprising user name table 50 may be entered utilizing user name “Stevens” from electronic mail item 26 and a likely alternative can be determined.

With reference now to FIG. 4B, a pictorial representation is illustrative of a domain name correction table, which may be utilized by electronic mail server 36 of FIG. 3 to implement the method and system of the present invention. As above, domain name table 70 includes a series of entry points such as “jonescorp” at reference numeral 72. Likely alternatives including “jonesinc” at reference numeral 74, “jonesco” at reference numeral 76 and “jonesltd” at reference numeral 78. Similarly, “martincorp” at reference numeral 80 provides another entry point into domain name table 70 and likely alternatives include “martininc” at reference numeral 82, “martinco” at reference numeral 84, “martincorp” at reference numeral 86 and “martinltd” at reference numeral 88 are listed.

Thus, if the domain name included within the address of electronic mail item 26 is not recognized by electronic mail server 36, domain name table 70 may be entered and a likely appropriate alternative is selected from this table.

Next, with reference to FIG. 4C, there is depicted a pictorial representation of a top level domain suffix correction table which may be utilized by electronic mail server 36 of FIG. 3 to implement the method and system of the present invention. As above, top level domain suffix table 90 includes a domain name with its top level suffix as the entry point, for example, “jonescorp.com” at reference numeral 92. Thereafter, likely appropriate alternatives are listed including “jonescorp.dot” at reference numeral 94, “jonescorp.org” at reference numeral 96 and “jonescorp.biz” at reference numeral 98. Similarly, “wilsonco.com” is another entry point depicted at reference numeral 100. Likely appropriate alternatives including “wilsonco.net” at reference numeral 102, “wilsonco.org” at reference numeral 104 and “wilsonco.biz” at reference numeral 106 are also listed. If the electronic mail item 26 or FIG. 2 arrives at electronic mail server 36 of FIG. 3 and the domain is recognized; however, the top level domain suffix is not recognized, a likely appropriate alternative may be selected by accessing top level domain suffix table 90.

Finally, referring to FIG. 4D, the last illustrative error correction table for use by electronic mail server 36 of FIG. 3 is depicted. FIG. 4D depicts a pictorial representation of a former employee correction table which may be utilized by electronic mail server 36 of FIG. 3 to implement the method and system of the present invention. As depicted, this table has as its entry points various expired electronic mail addresses for which a new electronic mail address is known. Thus, “stevens@jonecorp.com” is one entry point depicted as reference numeral 112. A new address for this individual is listed within former employee table 110 at reference numeral 114, which depicts “j.stevens@smithinc.com”. Similarly, another input to former employee table 110 is “willie@targetco.com” as depicted at reference numeral 116. The new address listed for that expired address is “william@hargrove.org” as depicted at reference numeral 118.

Thus, as those skilled in the art will appreciate upon reference to the foregoing, the error correction tables as depicted within FIGS. 4A-4D, represent a limited list of possible error correction tables which may be utilized to implement the address error recovery system of the present invention. Additional tables or processors may also be utilized such as, for example, a spell checker or phonetic equivalent table may be utilized to check for common name misspellings. Similarly, common misspellings may be discovered by removing all vowels and/or double letters from all possible addresses and the erroneous addressee name.

Other possible variations of the present invention may include enabling or disabling the automatic address error recovery system of the present invention based upon a user's job status or the domain identification of the sender.

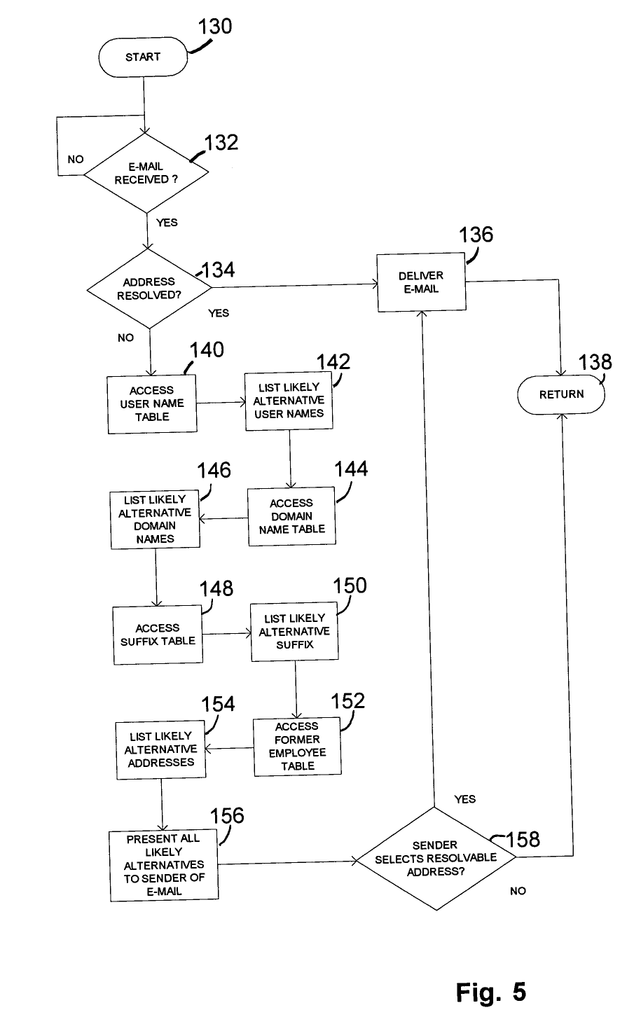

Finally, with reference to FIG. 5, there is depicted a high level logic flowchart which illustrates the method of the present invention as implemented within electronic mail server 36 of FIG. 3. As depicted, the process begins at reference numeral 130 and thereafter passes to block 132. Block 132 illustrates a determination of whether or not an electronic mail message has been received, and if not, the process merely iterates until such time as an electronic mail item has been received.

Still referring to block 132, in the event an electronic mail message has been received the process passes to block 134. Block 134 depicts a determination of whether or not the address for the received electronic mail item can been resolved and if so, the process passes to block 136. Block 136 illustrates the delivery of the electronic mail item and the process then passes to block 138 and returns.

Referring again to block 134, in the event the address of the received electronic mail item could not be resolved the process passes to block 140. Block 140 illustrates the accessing of the user name table depicted within FIG. 4A of the present invention. Thereafter, likely alternative user names are listed, as illustrated at block 142.

Next, the process passes to block 144 which illustrates the accessing of the domain name table depicted in FIG. 4B. Thereafter, the process passes to block 146, which depicts the listing of likely alternative domain names.

Thereafter, the process passes to block 148 which illustrates the accessing of the top level domain suffix table depicted in FIG. 4C. Likely alternative top level domain suffix are then listed, as depicted at block 150 of the high level logic flowchart of FIG. 5.

Finally, the expired or former employee address table depicted within FIG. 4D is accessed, as illustrated at block 152. Thereafter, likely alternative addresses are listed, as depicted at block 154. After processing through each of the error correction tables described above, the process passes to block 156.

Block 156 illustrates the presentation of all likely alternative addresses to the center of the e-mail. Those having ordinary skill in this art will appreciate that this may be accomplished by concatenating each portion of the electronic mail message with each likely alternative portion or, in the alternative, where a former employee table entry results in a current electronic mail address, the current electronic mail address may simply be presented. Thereafter, the process passes to block 158. Block 158 depicts a determination of whether or not the center has selected a resolvable address and if so, the process once again passes to block 136 which depicts the delivery of that electronic mail message item and the return of the process. Still referring to Block 158, in the event the user either does not select a resolvable address or no resolvable address is available, the process passes to block 138 and returns.

Upon reference to the foregoing, those skilled in the art will appreciate that the inventors herein have described a system whereby common, simple and predictable errors in electronic mail messages may be resolved automatically, greatly enhancing the efficiency of an electronic mail message system, reducing the time and effort required by a user to transmit an electronic mail item.

While the invention has been particularly shown and described with reference to a preferred embodiment, it will be understood by those skilled in the art that various changes in form and detail may be made therein without departing from the spirit and scope of the invention.

1. A method for automatic address error recovery in an electronic mail system, said method comprising the steps of:
receiving an electronic mail message from a designated sender, said electronic mail message having an address which comprises a user name and a domain name which includes a top level domain suffix;
transferring said received electronic mail message to a specified destination if that specified destination can be determined;
systematically determining at least one likely appropriate destination if said specified destination cannot be determined; and
automatically presenting said at least one likely appropriate destination to said designated sender of said electronic mail message.

2. The method for automatic address error recovery of claim 1 further included the step of transferring said received electronic mail message to said at least one likely appropriate destination in response to a selection of said at least one likely appropriate destination by said designated sender.

3. The method for automatic address error recovery of claim 1 wherein said step of systematically determining at least one likely appropriate destination if said specified destination cannot be determined further comprises the step of determining at least one common alternate spellings of said user name portion of said address.

4. The method for automatic address error recovery of claim 1 wherein said step of systematically determining at least one likely appropriate destination if said specified destination cannot be determined further comprises the step of determining at least one likely alternate domain names for said address.

5. The method for automatic address error recovery of claim 1 wherein said step of systematically determining at least one likely appropriate destination if said specified destination cannot be determined further comprises the step of determining at least one likely alternate top level domain suffix for said address.

6. The method for automatic address error recovery of claim 3 wherein said step of systematically determining at least one likely appropriate destination if said specified destination cannot be determined further comprises the step of determining at least one likely alternate domain names for said address.

7. The method for automatic address error recovery of claim 3 wherein said step of systematically determining at least one likely appropriate destination if said specified destination cannot be determined further comprises the step of determining at least one likely alternate top level domain suffix for said address.

8. The method for automatic address error recovery of claim 6 wherein said step of systematically determining at least one likely appropriate destination if said specified destination cannot be determined further comprises the step of determining at least one likely alternate top level domain suffix for said address.

9. The method for automatic address error recovery of claim 1 wherein said step of systematically determining at least one likely appropriate destination if said specified destination cannot be determined further includes the step of maintaining a list of expired addresses and a corresponding new address for each expired address and wherein said step of systematically determining at least one likely appropriate destination if said specified destination cannot be determined further comprises the step of determining if said address is within said list of expired addresses and a corresponding new address is listed therein.

10. A system for automatic address error recovery in an electronic mail system, said system comprising:
receiving an electronic mail message from a designated sender, said electronic mail message having an address which comprises a user name and a domain name which includes a top level domain suffix;
transferring said received electronic mail message to a specified destination if that specified destination can be determined;
systematically determining at least one likely appropriate destination if said specified destination cannot be determined; and
automatically presenting said at least one likely appropriate destination to said designated sender of said electronic mail message.

11. The method for automatic address error recovery of claim 10 further including means for transferring said received electronic mail message to said at least one likely appropriate destination in response to a selection of said at least one likely appropriate destination by said designated sender.

12. The method for automatic address error recovery of claim 10 wherein said means for systematically determining at least one likely appropriate destination if said specified destination cannot be determined further comprises means for determining at least one common alternate spellings of said user name portion of said address.

13. The method for automatic address error recovery of claim 10 wherein said means for systematically determining at least one likely appropriate destination if said specified destination cannot be determined further comprises means for determining at least one likely alternate domain names for said address.

14. The method for automatic address error recovery of claim 10 wherein said means for systematically determining at least one likely appropriate destination if said specified destination cannot be determined further comprises means for determining at least one likely alternate top level domain suffix for said address.

15. The method for automatic address error recovery of claim 12 wherein said means for systematically determining at least one likely appropriate destination if said specified destination cannot be determined further comprises means for determining at least one likely alternate domain names for said address.

16. The method for automatic address error recovery of claim 12 wherein said means for systematically determining at least one likely appropriate destination if said specified destination cannot be determined further comprises means for determining at least one likely alternate top level domain suffix for said address.

17. The method for automatic address error recovery of claim 15 wherein said means for systematically determining at least one likely appropriate destination if said specified destination cannot be determined further comprises means for determining at least one likely alternate top level domain suffix for said address.

18. The method for automatic address error recovery of claim 10 wherein said means for systematically determining at least one likely appropriate destination if said specified destination cannot be determined further includes means for maintaining a list of expired addresses and a corresponding new address for each expired address and wherein said means for systematically determining at least one likely appropriate destination if said specified destination cannot be determined further comprises means for determining is said address is within said list of expired addresses and a corresponding new address is listed therein.

19. A computer program product for automatic address error recovery in an electronic mail system, said computer program product comprising:
electronic media suitable for use within a computer system;
instruction means embodied within said electronic media for receiving an electronic mail message;
instruction means embodied within said electronic media for transferring said received electronic mail message to a specified destination if that specified destination can be determined;
instruction means embodied within said electronic media for systematically determining one likely appropriate destination if said specified destination cannot be determined; and
instruction means embodied within said electronic media for automatically presenting said at least one likely appropriate destination to said designated sender of said electronic mail message.
